(19) United States
(12) Patent Application Publication
(10) Pub. No.: US 2024/0243225 A1
(43) Pub. Date: Jul. 18, 2024

(54) COLOR FILTERING DBR FOR MICRO-LEDS

(71) Applicant: Snap Inc., Santa Monica, CA (US)

(72) Inventors: Peng Feng, Sheffield (GB); Jack Haggar, Sheffield (GB); Nicolas Poyiatzis, Sheffield (GB); Ye Tian, Sheffield (GB); Xiang Yu, Sheffield (GB)

(21) Appl. No.: 18/531,037

(22) Filed: Dec. 6, 2023

Related U.S. Application Data
(60) Provisional application No. 63/480,248, filed on Jan. 17, 2023.

(51) Int. Cl. H01L 33/10; H01L 25/075; H01L 33/00; H01L 33/32

(52) U.S. Cl. CPC H01L 33/105; H01L 25/0753; H01L 33/007; H01L 33/325

(57) ABSTRACT

A device includes a light emitting diode (LED) configured to emit light characterized by a peak wavelength, a lower wavelength band extending across lower wavelengths than the peak wavelength, and a higher wavelength band extending across higher wavelengths than the peak wavelength. The device also includes a reflector positioned in a first direction from the LED. The device also includes a distributed Bragg reflector (DBR) having a lower reflectance than the reflector, positioned in a second direction from the LED opposite the first direction, and configured to block light within a stopband overlapping a portion of the lower wavelength band or a portion of the higher wavelength band but not overlapping the peak wavelength, such that the DBR propagates filtered light in the second direction.

### CLAIM OF PRIORITY

This application claims the benefit of priority to U.S. Patent Application Ser. No. 63/480,248, filed on Jan. 17, 2023, which is incorporated herein by reference in its entirety.

### BACKGROUND

Group III-nitride light emitting diodes (LEDs), grown on a micrometer scale, are referred to as micro-sized LEDs or simply microLEDs, micro-LEDs, or μLEDs. Typically, the diameter of a μLED is 50 micrometers or less. μLEDs are expected to provide the basis for new generation displays and visible light communication (VLC) applications. III-nitride μLEDs exhibit a number of unique features for display applications compared with organic light-emitting diodes (OLEDs) and liquid crystal displays (LCDs). Unlike LCDs, III-nitride micro-displays using μLEDs are self-emissive. Monochromatic displays using μLEDs typically exhibit high resolution, high efficiency, and high contrast ratio. OLEDs are typically operated at a current density that is several orders of magnitude lower than semiconductor LEDs in order to maintain a reasonable lifetime. As a consequence, the luminance of OLEDs is low relative to III-nitride μLEDs. Furthermore, III-nitride μLEDs intrinsically exhibit long operation lifetime and chemical robustness in comparison with OLEDs. Therefore, it is expected that III-nitride μLEDs could potentially replace LCDs and OLEDs for high resolution and high brightness displays in a wide range of applications in the near future, such as smart phones.

### BRIEF DESCRIPTION OF THE SEVERAL VIEWS OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Some non-limiting examples are illustrated in the figures of the accompanying drawings in which:

FIG. 1 illustrates a top right isometric view of a red-green-blue (RGB) micro light emitting diode (microLED) pixel having a distributed Bragg reflector (DBR) in accordance with one example.

FIG. 2 illustrates a top view of an RGB microLED pixel array in accordance with one example.

FIG. 3 illustrates a bottom view of the RGB microLED pixel array of FIG. 2.

FIG. 4 illustrates a simplified side cross-sectional view of an RGB microLED pixel in accordance with one example.

FIG. 5 illustrates a flowchart showing operations of a method for fabricating a semiconductor device having a DBR in accordance with one example.

FIG. 6 illustrates a flowchart showing operations of a method for completing fabrication of the semiconductor device fabricated in accordance with the method of FIG. 5.

FIG. 7 illustrates a graph of reflectivity across light wavelengths of an example DBR, in accordance with one example.

FIG. 8 illustrates a graph of wavelengths of light against reflectance of an example green DBR and an example red DBR of an example filtering DBR, and against electroluminescent intensity for blue, green, and red microLEDs, in accordance with one example.

FIG. 9 illustrates a graph of light wavelength against bandwidth (measured as full width at half maximum) indicating apparent color for various points on the graph, in accordance with one example.

FIG. 10 illustrates a graph of wavelengths of light against reflectance of an example blue DBR, an example green DBR, and an example red DBR of an example resonant cavity DBR, and against electroluminescent intensity for blue, green, and red microLEDs, in accordance with one example.

### DETAILED DESCRIPTION

Examples of the present disclosure provide techniques for the fabrication of microLEDs. In some examples, a distributed Bragg reflector (DBR) is fabricated for a monolithic RGB microLED using electrochemical etching. The electrochemical (EC) etching is assisted by the formation of apertures through the layers of the DBR using dry-etching. By exposing the DBR layers prior to EC etching, the efficiency and effectiveness of the EC etching process is enhanced, thereby enhancing the emission of the light output and enabling the efficient preparation of complete, uniform semiconductor wafers between 2 inches and 8 inches in size.

Various examples described herein seek to address one or more of several technical problems. First, light emission by LEDs, and in particular monolithic RGB microLEDs, can be enhanced by the porosification of DBR layers using EC etching, assisted by the exposure of the DBR layers via the dry-etched apertures. A high quality DBR structure is grown through epitaxy and then rendered nanoporous using electrochemical etching, thereby avoiding ex-situ DBR deposition. Relative to ex-situ DBR fabrication, described examples allow for carefully controlled growth of highly uniform n-type gallium nitride (n-GaN) and DBR layers using metal organic vapor deposition across the entire semiconductor wafer. The dry-etched apertures enable the application of electrochemical etching conditions that enhance the uniformity of the EC etching result and increase the productivity of large scale wafer fabrication operations.

Second, the technical problem of the low electrical conductivity of a nanoporous DBR can be addressed by providing an n-type electrical contact (also called an n-contact herein) in direct physical contact with the n-GaN layer in some examples. The n-contact enables effective current injection and enhances current spread in the n-GaN layer. N-contact holes can be dry-etched through the DBR layers to enable the physical contact between the n-contact and the n-GaN layer.

Third, the technical problem of optical cross-talk between pixels in a horizontal pixel array can be addressed by forming a gap between pixels containing a light-blocking material.

Fourth, light emission can be further enhanced by forming an optical resonant cavity designed to enhance the light output of the various colored LEDs. The optical cavity, including the DBR, can be used for spectrum engineering. The light emission is collimated by the bottom DBR and a top conductive mirror.

Fifth, the DBR can act as a filter to purify the color of one or more of the LEDs by shifting and narrowing the wavelength band of the LEDs' emitted light.

Other solutions to technical problems may be provided in the disclosure, explicitly or implicitly, as will be appreciated by a skilled person.

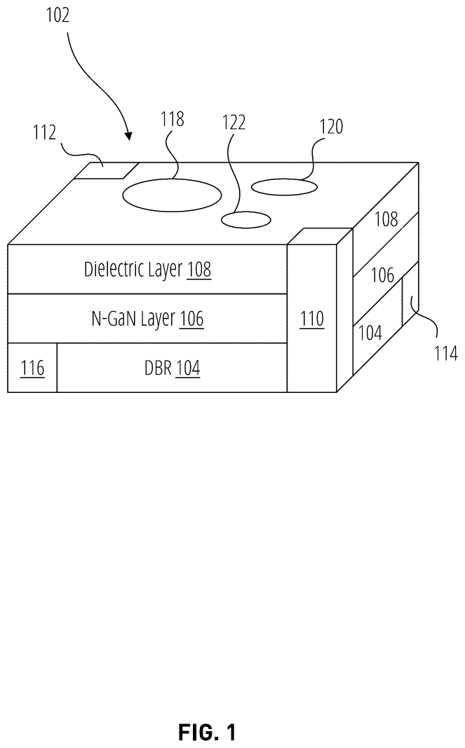

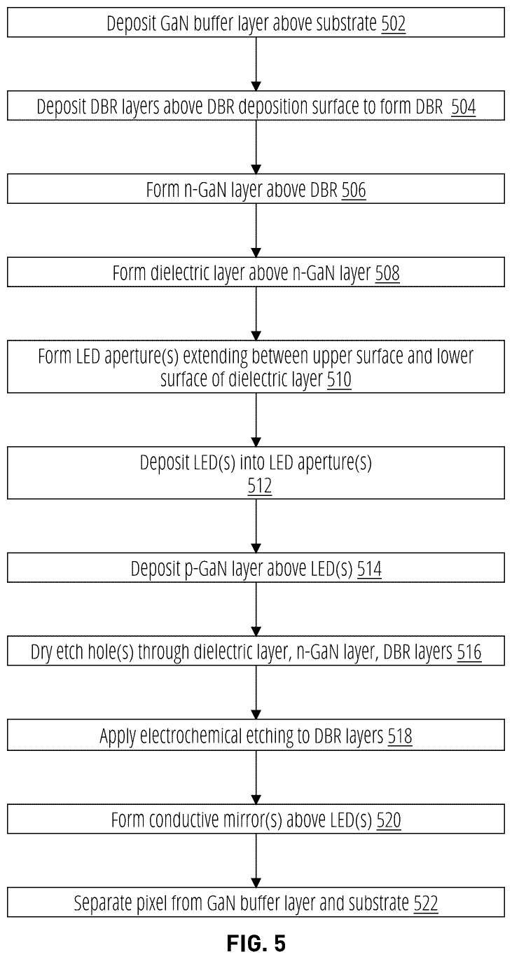

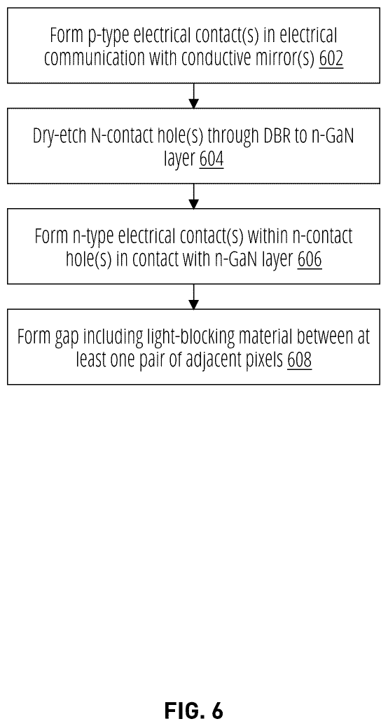

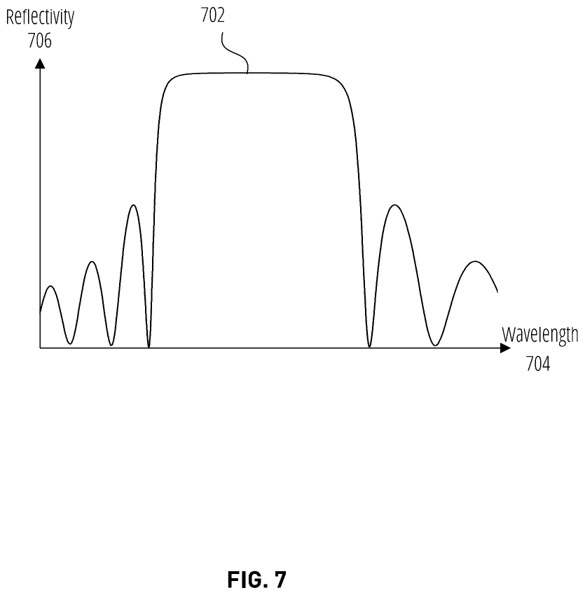

Examples of semiconductor devices fabricated according to techniques described herein will now be described with reference to FIG. 1 through FIG. 4. Example methods for manufacturing semiconductor devices will then be described with reference to FIG. 5 and FIG. 6. Various properties of the example semiconductor devices will then be described with reference to FIG. 7 through FIG. 9.

FIG. 1 shows an example semiconductor device, shown as a substantially rectangular pixel 102, specifically a monolithic RGB microLED pixel. The pixel 102 includes a DBR 104, an n-GaN layer 106, and a dielectric layer 108 grown as successive layers using epitaxy, as described below. A first aperture 110 and a second aperture 112 are dry-etched through the DBR 104, n-GaN layer 106, and dielectric layer 108 at two diagonally opposite corners of the pixel 102. A first n-type contact 114 and a second n-contact 116 occupy N-contact holes dry-etched through the DBR 104 in the two remaining diagonally-opposite corners of the pixel 102, e.g., those corners not defining the apertures 110, 112.

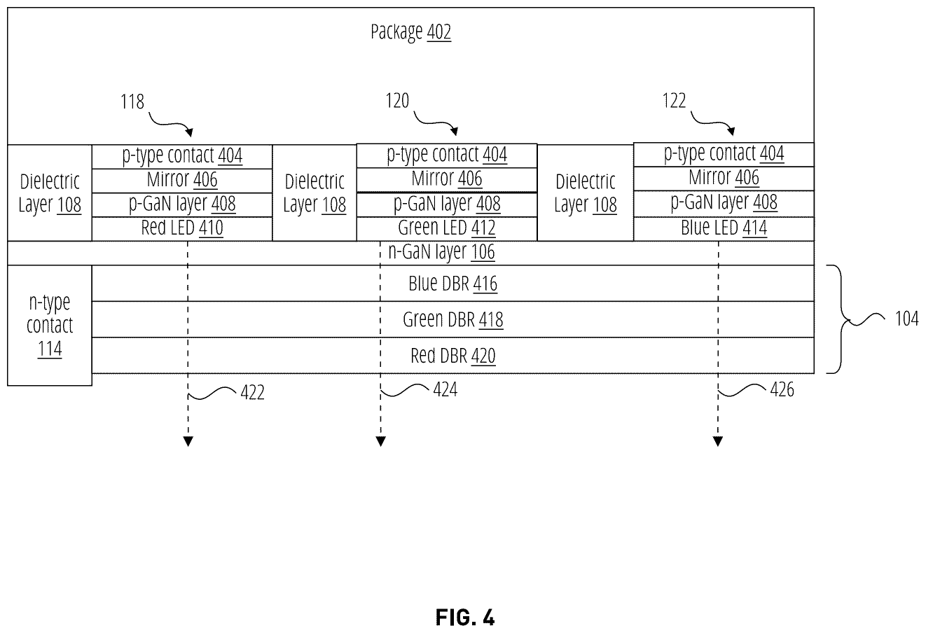

The dielectric layer 108 defines one or more LED apertures, shown as three dry-etched microLED apertures: a first LED aperture 118, a second LED aperture 120, and a third LED aperture 122. In the illustrated example, each LED aperture 118, 120, 122 houses a microLED of a distinct color, such as a red LED 410 in the first LED aperture 118, a green LED 412 in the second LED aperture 120, and a blue LED 414 in the third LED aperture 122. Further details of the structures formed within each LED aperture are described below with reference to FIG. 4 and FIG. 5. For the purposes of this disclosure, the terms LED and microLED will be used interchangeably unless otherwise indicated.

In the illustrated examples, the LED apertures differ from each other in size. In some examples, it may be desirable to grow a red LED within a relatively large LED aperture, a green LED within a medium-sized LED aperture, and a blue LED within a relatively small LED aperture, given the relative wavelengths of light generated by the respective LED colors and the relative intensity of the light emitted thereby. In various examples, the LED apertures can differ in number, size, and placement from those shown in the illustrated examples.

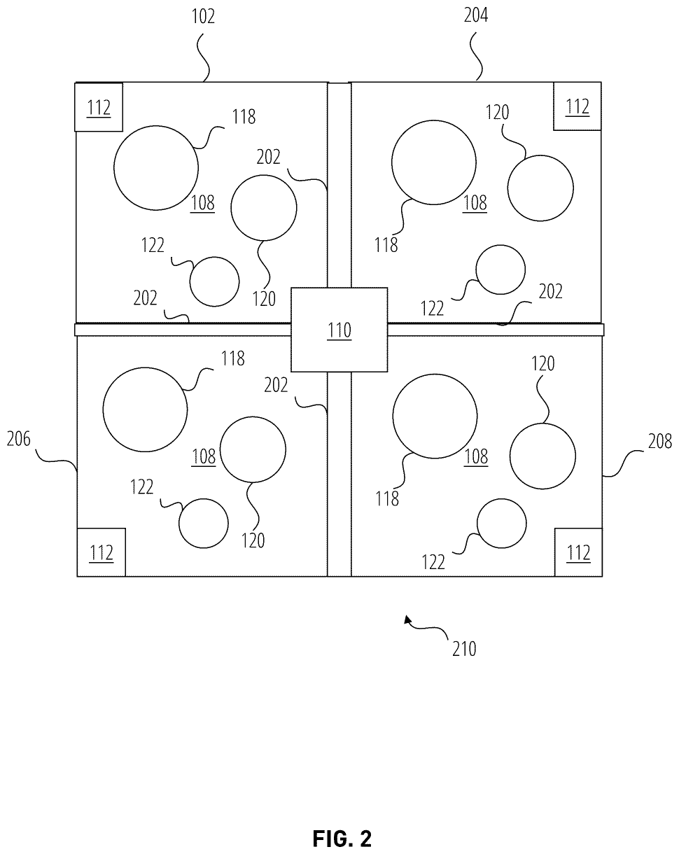

FIG. 2 shows a top view of a horizontal pixel array 210, specifically an RGB microLED pixel array, having four pixels. It will be appreciated that microLEDs are typically fabricated on wafers containing arrays of thousands of pixels; accordingly, the four pixels shown in FIG. 2 are intended as an illustration of an example pixel array structure showing the inter-relation of individual pixels thereof.

The pixel 102 of FIG. 1 is shown as first pixel 102 in the upper left corner; the pixel array 210 also includes a second pixel 204, a third pixel 206, and a fourth pixel 208. The dielectric layer 108 of each pixel is visible from the top view, as are the first LED aperture 118, second LED aperture 120, and third LED aperture 122 thereof. The pixels are arranged such that the first aperture 110 of each pixel is jointly formed with the first aperture 110 of each of its adjacent pixels. Similarly, the second aperture 112 of each pixel would be jointly formed with the second aperture 112 of each of its adjacent pixels in the context of a larger pixel array. This joint formation of the apertures 110, 112 between groups of adjacent pixels allows a single large hole to be dry-etched in a wafer defining the pixel array instead of separate holes for each individual pixel.

As shown in FIG. 1, the apertures 110, 112 are located at diagonally opposite corners of each pixel. This not only allows the apertures 110, 112 to be jointly formed with those of three adjacent pixels, but it also ensures that the apertures 110, 112 do not intersect with the path of the light emitted by the microLEDs, as further explained below. It will be appreciated that the placement, number, and/or shape of the apertures 110, 112, as well as the placement, number, and/or shape of the LED apertures, can be varied in different examples.

In the illustrated example, a gap 202 is defined between each pair of adjacent pixels. At least a portion of the gap 202 includes a light-blocking material, such that optical cross-talk between the adjacent pixels is reduced or eliminated. The gap 202 may be omitted in some examples.

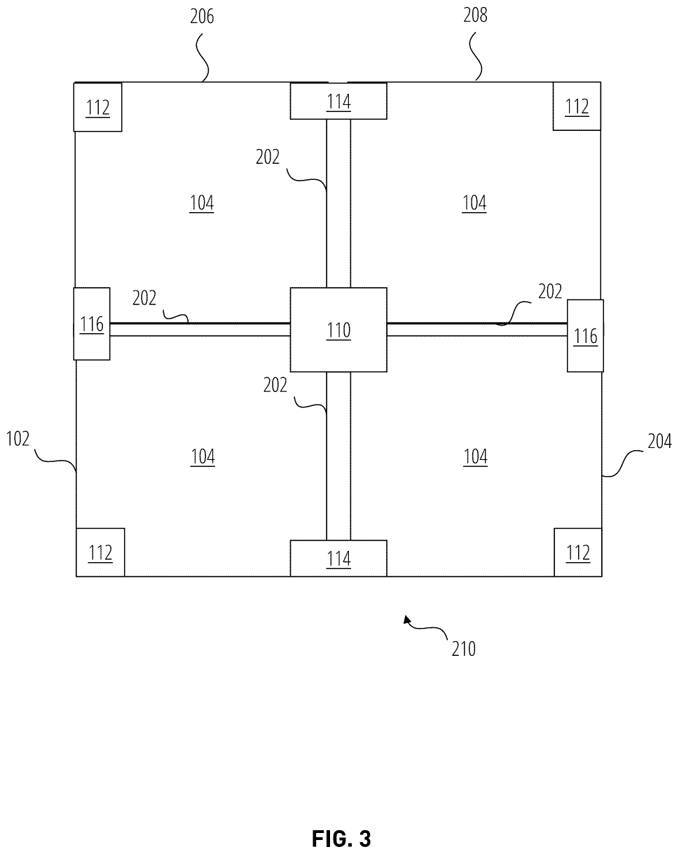

FIG. 3 shows a bottom view of the example pixel array 210 of FIG. 2. The DBR 104 of each pixel is visible. N-contact holes are dry-etched in two corners of the DBR of each pixel, as shown in FIG. 1, with a first n-type contact 114 resident within the first N-contact hole and a second n-contact 116 resident within the second N-contact hole. Similar to the apertures 110, 112 shown in FIG. 2, the pixels are arranged such that the N-contact holes and their resident n-type contacts 114, 116 can be jointly formed between sets of two or four adjacent pixels. It will be appreciated that, in the context of a larger pixel array, the n-type contacts 114, 116 could be formed jointly among each set of four adjacent pixels.

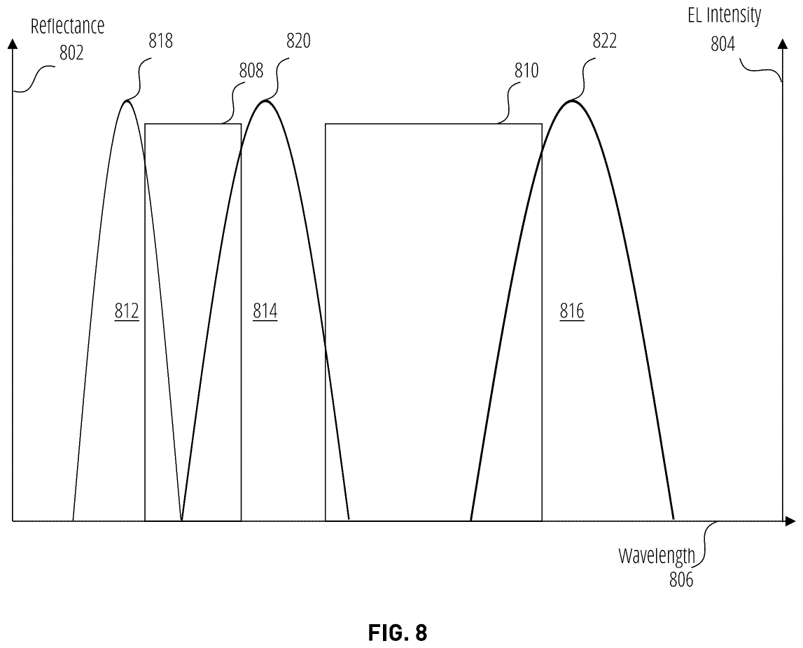

FIG. 4 illustrates a simplified side cross-sectional view of an RGB microLED pixel, similar to the pixel 102 of FIG. 1, but wherein the three LEDs are shown side by side in cross-section for the sake of simplifying the figure. The DBR 104 is shown in the illustrated example as including a red DBR 420 and a green DBR 418, as described in greater detail below with reference to FIG. 5 and FIG. 8. An n-type electrical contact (shown as first n-type contact 114) is shown in contact with the n-GaN layer 106 and housed within a dry-etched n-contact hole.

The first LED aperture 118, second LED aperture 120, and third LED aperture 122 are shown extending from an upper surface to a bottom surface of the dielectric layer 108. Within each LED aperture 118, 120, 122 is formed a stack of layers: an LED (red LED 410, green LED 412, and blue LED 414 respectively), a p-GaN layer 408, a conductive mirror 406, and a p-type electrical contact (p-type contact 404). In some examples, the conductive mirrors 406 and/or the p-type contacts 404 may be formed above upper surfaces of the dielectric layer 108 instead of being formed within the LED apertures, and may differ in number, placement, and/or shape from those shown in the illustrated example; however, examples providing a separate conductive mirror 406 and p-type contact 404 for each LED enable the independent control of each LED by a current source supplying current to flow between each p-type contact 404 and the n-type contact 114 (and second n-type contact 116, not shown in FIG. 4).

A package 402 for the pixel, or for an array of pixels, can be bonded to the top surface of the dielectric layer 108 for assembly of a final product. The package 402 may include a backplane for the pixel array having electrical contacts configured to supply current to each p-type contact 404 of each pixel in the pixel array.

In use, the pixel shown in FIG. 4 emits light from each LED through the DBR 104. The light (shown as red light 422 from the red LED 410, green light 424 from the green LED 412, and blue light 426 from the blue LED 414) is emitted in a light emission direction as indicated by the arrows of 422, 424, 426 (shown as a downward direction based on the orientation of the pixel in FIG. 4). In some examples, the distance between the DBR 104 (or the red DBR 420, green DBR 418, or the blue DBR 416) and each conductive mirror 406 defines a respective length of an optical cavity for the respective LED. These distances may be the same or different for each LED in various examples. These distances can be determined at least in part by the thickness of the p-GaN layer 408 within each LED aperture and the thickness of the n-GaN layer 106. The distances can also be determined at least in part by the total distance from the quantum well layer(s) of the LED (e.g., the red LED 410) to the corresponding DBR (e.g., red DBR 420). In some examples, the DBR can include one or more additional n-GaN layers (not shown in FIG. 4) separating the color-specific DBRs, and the thicknesses of these additional n-GaN layers can be selected to position the color-specific DBRs at specific distances from their respective conductive mirrors. Thus, the lengths of the optical cavities defined by the distances between each color-specific DBR and its respective conductive mirror can be selected by adjusting one or more parameters, including: the thicknesses of the DBR layers, the thicknesses of the additional n-GaN layers separating the color-specific DBRs, the thickness of the n-GaN layer 106, and the thickness of the p-GaN layer 408 within each LED aperture.

The conductive mirrors 406 are configured to have higher reflectance than the DBR 104; in some examples, each respective conductive mirror 406 is configured to have high reflectance for at least a portion of the spectrum of light of its respective LED. Due to the higher reflectance of the conductive mirrors 406 relative to the reflectance of the DBR 104, the light 422, 424, 426 from each LED is emitted from the pixel through the DBR 104 in the light emission direction indicated by the arrows, shown as a downward direction in FIG. 4. The reflection of the light between the conductive mirrors 406 and the DBR 104 also results in collimation of the emitted light.

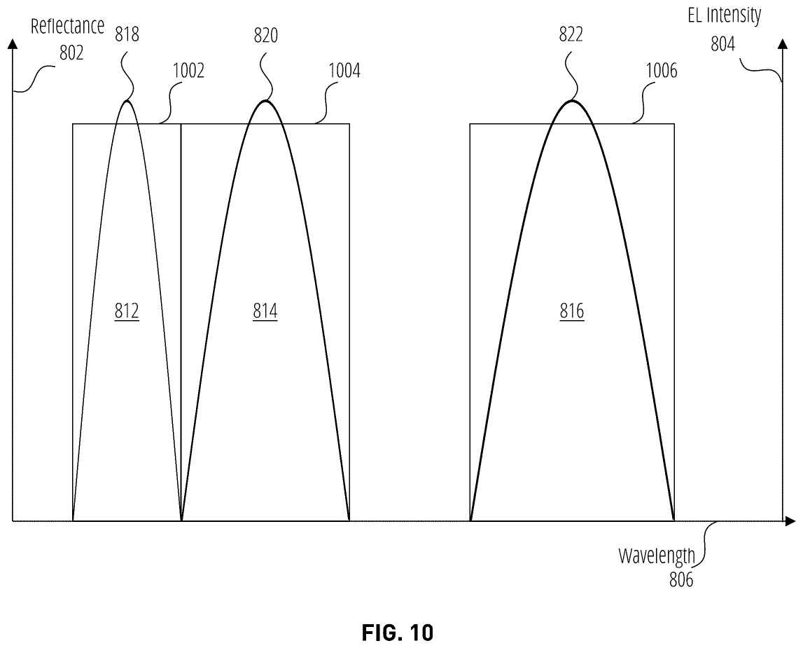

In some examples, one or more of the optical cavities are resonant cavities generating resonance for at least one wavelength of light emitted by the respective LED. By adjusting the length of each optical cavity—for example, by adjusting the thicknesses of the various layers as described above—a resonant cavity LED (RCLED) structure can be provided to enhance the emission of micro-LEDs, e.g., LEDs 410, 412, 414. Examples of light emission enhancement performed by the RCLED structure are described below with reference to FIG. 7 and FIG. 10. In some examples, the length of each resonant cavity is important for RCLED performance. Conventional RCLED fabrication uses grinding or dry etching followed by film deposition, which presents serious challenges in achieving good uniformity across an entire wafer. In some examples, the fabrication techniques described herein with reference to FIG. 5 below may address this technical problem by providing high uniformity of RCLED fabrication across entire wafers up to 12 inches in size.

In conventional micro-LED fabrication, collimation of the light emitted by the microLEDs typically requires the use of a specially designed lens. In some examples, the fabrication techniques described herein with reference to FIG. 5 below may address this technical problem by avoiding the need for a complicated packaging process including a specially designed lens to focus the emission in one direction. Instead, by providing the DBR 104, and optionally also providing resonant cavities for one or more of the LEDs, some examples described herein provide collimation of the light emitted by one or more of the LEDs using a relatively simple structure fabricated using a relatively simple fabrication process.

Thus, in some examples using a RCLED design, the DBR 104 includes one or more color-specific DBRs, such as a first plurality of DBR layers forming a red-light DBR (e.g., red DBR 420) configured to reflect light at a wavelength of light emitted by the red microLED, a second plurality of DBR layers forming a green-light DBR (e.g., green DBR 418) configured to reflect light at a wavelength of light emitted by the green microLED, and a third plurality of DBR layers forming a blue-light DBR (e.g., blue DBR 416) configured to reflect light at a wavelength of light emitted by the blue microLED. Similarly, some examples using a RCLED design are configured such that the conductive mirror(s) 406 and the red-light DBR form a resonant cavity generating resonance for the wavelength of light emitted by the red microLED, the conductive mirror(s) 406 and the green-light DBR form a resonant cavity generating resonance for the wavelength of light emitted by the green microLED, and the conductive mirror(s) 406 and the blue-light DBR form a resonant cavity generating resonance for the wavelength of light emitted by the blue microLED.

In some examples using a RCLED design, a semiconductor device is formed having one or more LEDs emitting light from respective resonant cavities having lengths tuned to a wavelength of the light emitted by the LED resident within the given resonant cavities, using the fabrication techniques described herein. In some examples, each LED has a different spectral power distribution, such as the red light 422 emitted by the red LED 410, the green light 424 emitted by the green LED 412, and the blue light 426 emitted by the blue LED 414. In some examples, each optical cavity is defined by a respective reflector (e.g., a respective conductive mirror 406) and the DBR, such as the respective color-specific DBR 420, 418, 416 for each respective LED 410, 412, 414. Each color-specific DBR can be formed at a different distance from its respective conductive mirror to achieve the desired length for its optical cavity: for example, as shown in FIG. 4, the red DBR 420 is positioned relatively far from the conductive mirror 406 above the red LED 410, in order to create a first resonant cavity for red-light wavelengths (e.g., around 610 nm), whereas the blue DBR 416 is positioned relatively closer in order to create a third resonant cavity for blue-light wavelengths (e.g., around 480 nm), and the green DBR 418 is positioned between the red DBR 420 and blue DBR 416 in order to create a second resonant cavity for green-light wavelengths (e.g., around 525 nm).

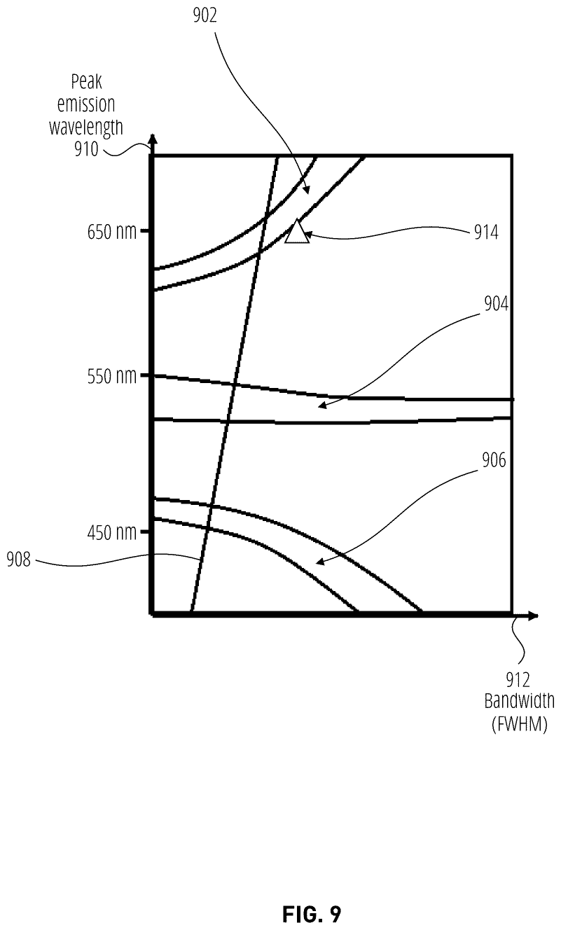

In some examples, the DBR 104 is configured to act as a filter for the light emitted by one or more of the LEDs. The bandwidth and/or center frequency of the light emitted by one or more of the LEDs can be filtered by the DBR 104 to affect the perceived color of the light, for example to achieve an apparently purer color centered on a selected wavelength for each respective color. Examples of filtering of light by the DBR 104 in various examples are described in greater detail below with reference to FIG. 7, FIG. 8, and FIG. 9.

In some examples using a filtering DBR, the components of the pixel or other semiconductor device are arranged differently than in the illustrated examples but nonetheless use the filtering properties of the DBR to enhance the perceived purity of the color of the emitted light. Thus, some examples include a reflector (e.g., conductive mirror 406) positioned in a first direction from an LED (e.g., a microLED), and a DBR 104 positioned in a second direction from the LED opposite the first direction, wherein the DBR 104 has a lower reflectance than the reflector. The DBR 104 is configured to block light within a stopband overlapping a portion of the lower wavelength band or a portion of the higher wavelength band but not overlapping the peak wavelength, such that the DBR 104 propagates filtered light in the second direction.

In some examples, the LED is a red LED configured to emit light with a peak wavelength between 550 nanometers (nm) and 750 nm, and the stopband overlaps a portion of the lower wavelength band of the LED. In some examples, the peak wavelength of the light of the red LED is between 600 nm and 620 nm, and the stopband is centered on a wavelength between 550 nm and 580 nm. FIG. 8 illustrates an example of such a configuration of the red DBR stopband 810 and red light band 816 characterizing the emission of the red LED 410.

In some examples, a second LED (such as a green LED) is also included in the semiconductor device. The second LED is configured to emit light characterized by a second LED peak wavelength lower than the peak wavelength of the first LED (e.g., the red LED), a second LED lower wavelength band, and a second LED upper wavelength band. The stopband of the DBR overlaps a portion of the lower wavelength band and a portion of the second LED upper wavelength band. FIG. 8 illustrates an example of such a configuration of the red DBR stopband 810 and green light band 814 characterizing the emission of the green LED 412.

In some examples, the reflector and the DBR define a resonant cavity having a length effective to collimate the light emitted by the LED, as described above. In some examples, a pixel can be manufactured having one or more color-specific DBRs acting as filtering DBRs as well as one or more color-specific DBRs acting as RCLED DBRs as described above. For example, a pixel could use a filtering DBR to purify the color of the light emitted by a red LED, and RCLED structures to enhance the light emitted by the green LED and blue LED. It will be appreciated that various example devices can be fabricated featuring other configurations or sub-combinations of LEDs of the same and/or different colors using filtering and/or RCLED DBR configurations.

Thus, the DBR 104 can be used to provide spectrum engineering for the wavelengths of the light emitted by a semiconductor device, in accordance with various examples described herein, for example with reference to FIG. 7 through FIG. 10 below.

It will be appreciated that, although the three LED apertures are shown in FIG. 4 as having the same vertical and horizontal dimensions as each other, in various examples (such as pixel 102 shown in FIG. 1) the LED apertures may differ from each other in their horizontal dimensions. Furthermore, in some examples the vertical dimensions of the LED apertures and/or the layers deposited within each LED aperture may differ from each other in order to optimize the resonance capability of each optical cavity for its respective color of light emitted by its respective LED.

FIG. 5 illustrates an example method for fabricating a semiconductor device having a DBR. Although the example method depicts a particular sequence of operations, the sequence may be altered without departing from the scope of the present disclosure. For example, some of the operations depicted may be performed in parallel or in a different sequence that does not materially affect the function of the method.

The example method is described with reference to the fabrication of the example pixel 102 of FIG. 1 or FIG. 4 and/or the example pixel array 210 of FIG. 2 and FIG. 3. It will be appreciated that, in other examples, the method can be performed to fabricate devices having different structures or different characteristics from those previously described example pixels and pixel arrays.

According to some examples, the method includes depositing a GaN buffer layer above a substrate at operation 502. A suitable substrate for epitaxial semiconductor fabrication can be used, such as a sapphire substrate cut at a (0001) orientation. The substrate typically has a flat surface—in the described examples, the substrate surface is described as facing upward, and each layer is described as being deposited above or on top of the previous layer, but it will be appreciated that the orientation of the flat surface of the substrate is arbitrary. Directional terms, such as “up”, “down”, “above”, and “below”, will be understood to refer to a frame of reference in which the flat surface of the substrate faces a direction defined as “up”.

A template for the semiconductor device (e.g., pixel 102 or pixel array 210) is grown on the substrate using metal-organic vapor-phase epitaxy (MOVPE). The template includes a GaN buffer layer. The substrate and the GaN buffer layer may be referred to jointly as the “DBR deposition surface” because they provide a surface on which the layers of the DBR 104 are deposited. After the GaN buffer layer is grown, the DBR 104 and n-GaN layer 106 are grown to complete the template, as described below. As used herein, the terms “grow” and “deposit” are used interchangeably to refer to epitaxial growth or deposition of material to form a layer of a semiconductor device.

According to some examples, the method includes depositing DBR layers above the DBR deposition surface to form the DBR 104 at operation 504. The DBR 104 is formed by the sequential deposition of multiple pairs of alternating adjacent layers. Each pair of alternating adjacent layers includes a silicon doped layer containing gallium nitride (GaN) and silicon (Si), and an un-doped layer containing gallium nitride (GaN) and having a lower silicon content than the silicon doped layer. In some examples, the undoped layers are lightly doped with silicon, e.g., they are less heavily doped with silicon than the silicon doped layers. In some examples, other substances such as germanium (Ge) may be used to dope some or all of the layers of the DBR.

In some examples, the silicon doped layers are silicon doped AlGaN containing aluminum at a concentration greater than 0% and less than 5%. The use of aluminum in the silicon doped layers may realize certain advantages, such as improving the conductivity by further increasing the doping level without changing the crystal quality of the silicon doped layer. Due to the small amount of aluminum used in the silicon doped layers (e.g., 0-5%), the lattice-mismatch between the silicon doped AlGaN layers and the undoped GaN layers can be minimized in some examples. Low or negligible lattice mismatch may result in significantly improved performance of the DBR 104 relative to conventional DBR structures.

The epitaxial growth process used to form the layers of the DBR at operation 504 may address one or more technical problems. The precise control of thickness and integration uniformity enabled by the epitaxy techniques described herein can be used in some examples to provide a DBR having improved uniformity and quality across a whole semiconductor wafer relative to conventional dry etching, grinding, and chemical vapor deposition (CVD) approaches applied across a large wafer area. The described techniques may also provide highly uniform n-GaN layers across the whole semiconductor wafer. Furthermore, the refractive indices of the DBR layers can be easily adjusted by changing the size of the pores created during porosification, thereby modifying the center wavelength and/or bandwidth of the DBR stopband.

As discussed in greater detail below with reference to FIG. 7, the layers of the DBR can be configured to reflect a specific portion of the spectrum of the light from the one or more LEDs by configuring the thicknesses of the DBR layers. In some examples, each DBR layer can be deposited at operation 504 to have a thickness L=λ/(4n) wherein λ is the desired center wavelength for the DBR stopband and n is the refractive index of that DBR layer. Thus, the center wavelength of the stopband for DBR reflectance can be easily controlled by adjusting a thickness ratio between each layer of each pair of alternating adjacent layers of the DBR structure. Each pair of alternating adjacent layers of the DBR is characterized by a ratio between the thickness of the silicon doped layer and a thickness of the un-doped layer, and the ratios of the pairs of alternating adjacent layers can be configured to determine a center wavelength of the stopband of the DBR.

As discussed above with reference to FIG. 4 and below with reference to FIG. 10, in some examples the DBR may include one or more color-specific DBRs, each color-specific DBR including a respective plurality of DBR layers, and each color-specific DBR being configured to reflect a distinct respective portion of the spectrum of the light from the one or more LEDs (e.g., from a single distinctly colored LED). In some examples, the color-specific DBRs can be separated from each other by deposition, between two color-specific DBRs, of an additional n-GaN layer, as described above. These additional n-GaN layers can be used in some examples to position the color-specific DBRs to form resonant cavities of specific lengths defined by the color-specific DBRs and their respective conductive mirrors 406. Each additional n-GaN layers is deposited after deposition of a lower color-specific DBR (e.g., after deposition of red DBR 420 in FIG. 4) and before deposition of the next, higher color-specific DBR (e.g., before deposition of green DBR 418 in FIG. 4).

It will be appreciated that some of the structures and fabrication operations described herein are not limited to microLED devices or microLED fabrication, and may be applicable to the fabricating of wafer scale DBRs having high uniformity and performance, for use in any suitable application. However, some examples described herein may also address the technical problem of how to efficiently fabricate an effective DBR for polychromatic (e.g., RGB) LEDs, including microLEDs.

According to some examples, the method includes forming an n-GaN layer 106 above the DBR 104 at operation 506. The n-GaN layer 106 acts as a cathode for the LEDs deposited at operation 512 described below.

According to some examples, the method includes forming a dielectric layer 108 above the n-GaN layer at operation 508. After the template (e.g., the GaN buffer layer, the DBR 104, and the n-GaN layer 106) has been grown, the dielectric layer 108 is deposited above the n-GaN layer 106. In some examples, the dielectric layer 108 is substantially composed of silicon dioxide (SiO₂). In other examples, different materials may be substituted for SiO₂: for example, a layer of any suitable dielectric material could be used in place of SiO₂, such as a silicon oxide (SiOₓ) or a silicon nitride (SiNₓ).

According to some examples, the method includes forming one or more LED apertures extending between upper surface and lower surface of the dielectric layer 108 at operation 510. In some examples, the LED apertures are micro-holes formed by dry-etching from the upper surface of the dielectric layer to the n-GaN layer 106. The LED apertures can have various differing sizes in some example, as shown in example pixel 102, or they can be uniform in size in other examples. In some examples, the LED apertures include a red LED aperture (e.g., first LED aperture 118) for housing a red LED 410, a green LED aperture (e.g., second LED aperture 120) for housing a green LED 412, and a blue LED aperture (e.g., third LED aperture 122) for housing a blue LED 414.

According to some examples, the method includes depositing LED(s) into the LED aperture(s) at operation 512. In some examples, an LED is grown in each LED aperture using epitaxy. In some examples, the LED is grown as a superlattice structure including multiple quantum well layers. In some examples, such as those illustrated in FIG. 1 through FIG. 4, each LED aperture 118, 120, 122 is a dry-etched micro-hole and a single pixel includes a red LED 410 grown within the first LED aperture 118, a green LED 412 grown within the second LED aperture 120, and a blue LED 414 grown within the third LED aperture 122. However, it will be appreciated that different examples may deposit different types of LEDs into the one or more LED apertures of the semiconductor device.

According to some examples, the method includes depositing a p-GaN layer above the LED(s) at operation 514. In some examples, such as those illustrated in FIG. 1 through FIG. 4, each LED has a respective p-GaN layer 408 grown above the LED within its respective LED aperture. The p-GaN layer 408 acts as an anode for the respective LED.

According to some examples, the method includes dry etching hole(s) extending from the upper surface of the dielectric layer 108 through the dielectric layer 108, the n-GaN layer 106, and DBR 104 at operation 516. In the examples illustrated in FIG. 1 through FIG. 3, the dry etched holes are first aperture 110 and second aperture 112, and may be formed at the juncture of four pixels in a pixel array to create a single large aperture shared by the four pixels. In some examples, the number, location, and/or shape of the apertures 110, 112 may be different, as long as the location and shape of the apertures 110, 112 does not damage the LEDs or other components and does not interfere with the paths traveled by the light emitted by the LEDs. A single large aperture shared by multiple pixels may result in superior exposure of the DBR layers of each pixel to the electrochemical etching process described at operation 518 below. Furthermore, by locating the two apertures 110, 112 at diagonally opposite corners of a pixel, the electrochemical etching operation 518 may achieve relatively uniform porosification across the DBR layers.

In some examples, the apertures formed at operation 516 can be dry etched through only a subset of the DBR layers instead of extending through all DBR layers. However, it may be advantageous to extend the apertures to the bottom of the DBR to expose all layers thereof, in order to maximize the exposure of all DBR layers to the EC etching process and thereby maximize the porosification of all silicon doped layers of the DBR.

According to some examples, the method includes applying electrochemical etching to the DBR layers via the at least one aperture at operation 518. The electrochemical (EC) etching operation 518 is intended to transform the silicon doped layers of the DBR into nonporous structures, assisted by the exposure of the DBR layers through the dry-etched apertures 110, 112.

In some examples, the electrochemical etching is applied with relatively low current bias in order to effectively porosify the silicon doped layers of the DBR without damaging the n-GaN layer 106. In some examples, the current bias used by the EC etching operation 518 is between 3.5V and 10V.

In some examples, the electrochemical etching operation 518 is performed using an acid, such as nitric acid (HNO₃), at a molarity between 0.3M and 15.8M. In other examples, different acids can be used, such as hydrofluoric acid (HF), hydrochloric acid (HCL), sulfuric acid (H₂SO₄), or acetic acid (CH₃COOH).

In some examples, the electrochemical etching is performed at room temperature, such as a temperature between 0° C. and 60° C. Higher temperatures can accelerate the electrochemical etching process, but may also damage the structure.

Thus, in some examples, the electrochemical etching is performed using low current bias and 1M HNO₃, at room temperature.

Conventional electrochemical etching techniques exhibit limitations in etching bottom DBR structures below other layers of the semiconductor device, and the high current bias required by such techniques to properly transform the bottom DBR layers will typically damage the upper portions of the semiconductor device, such as the LEDs and n-GaN layer. By using dry-etched holes (e.g., apertures 110, 112) to fully expose the heavily silicon doped layers of the DBR 104, the electrochemical etching operation 518 described herein can more effectively and quickly transform the silicon doped layers of the DBR 104 into nanoporous structures without damaging other components of the semiconductor device. The apertures 110, 112 assist the ion transfer of acid in the DBR layers, thereby reducing the time required to perform electrochemical etching on a whole wafer scale. In some examples, the semiconductor wafer, and in particular the DBR 104, exhibits high reflectance and high uniformity at large scale fabrication after the EC etching operation 518.

In some examples, the electrochemical etching process of operation 518 can efficiently transform the silicon doped layers of the DBR into nanoporous structures having a large refractive index difference relative to the undoped layers of the DBR. Compared to the conventional DBR fabrication techniques, the electrochemical etching process of operation 518 may require less epitaxial growth time and result in a DBR having higher reflectance.

According to some examples, the method includes forming conductive mirror(s) above the LED(s) at operation 520. A conductive mirror 406 is deposited above one or more of the LED structures in the LED apertures. The reflectance of the conductive mirror 406 is higher than the reflectance of the DBR 104. In the examples illustrated in FIG. 1 through FIG. 4, a separate conductive mirror 406 is formed in each micro-hole (e.g., in each LED aperture). In some such examples, each conductive mirror 406 is separately configured to optimize reflectance of the spectrum of light emitted by its respective LED. In other examples, a single conductive mirror layer is deposited as a unity above the LED structures, and subsequently separated into distinct conductive mirrors by dry etching.

According to some examples, the method includes separating the pixel 102 from the GaN buffer layer and substrate at operation 522. In some examples, this operation 522 is performed after a further operation (not shown) of wafer bonding: e.g., bonding the backplane or other package 402 to the upper surface of the dielectric layer 108. In some examples, the pixel is fabricated as part of the pixel array 210, and the entire pixel array 210 is separated from the GaN buffer layer and substrate at operation 522.

It will be appreciated that some examples may omit or vary one or more of the operations of the example method described above to fabricate a semiconductor device having some or all of the characteristics of the example devices described herein. In some examples, the DBR 104 is formed as a plurality of layers above a substrate surface. The DBR 104 is configured to block light within a stopband. Above the DBR 104, at least one LED is grown. The LED is configured to emit light characterized by a peak wavelength, a lower wavelength band, and a higher wavelength band as described above. In a filtering DBR design, the stopband of the DBR 104 overlaps a portion of the lower wavelength band or a portion of the higher wavelength band but not the peak wavelength. A reflector (e.g., conductive mirror 406) is formed above the LED, with a higher reflectance than the DBR 104.

In some examples, other components of the described devices are formed by the fabrication method, such as the dielectric layer 108, one or more dry etched micro-hole(s) for growing the LED(s) within, the n-GaN layer 106, the p-GaN layer 408, and so on.

FIG. 6 illustrates an example method for completing fabrication of the semiconductor device fabricated in accordance with the method of FIG. 5. Although the example method depicts a particular sequence of operations, the sequence may be altered without departing from the scope of the present disclosure. For example, some of the operations depicted may be performed in parallel or in a different sequence that does not materially affect the function of the method.

According to some examples, the method includes forming p-type electrical contact(s) in electrical communication with the conductive mirror(s) 406 at operation 602. The p-type contacts 404 are formed from a conductive material suitable for providing current to a semiconductor device, such as a microLED pixel. As described above with reference to the formation of the conductive mirrors 406 at operation 520, in various examples the p-type contacts 404 can either be formed separately within or above each LED aperture, or the p-type contacts 404 can be formed as a unitary structure before being separated into discrete p-type contacts 404 by dry-etching. By providing a distinct p-type contact 404 and a distinct conductive mirror 406 for each LED, the current supplied to each LED can be independently controlled, thereby controlling the intensity of light emitted by each of the multi-colored LEDs independently.

According to some examples, the method includes dry-etching one or more n-contact hole(s) through the DBR 104 to the n-GaN layer 106 at operation 604. The placement of n-contact holes at diagonally opposite corners of the pixel 102 may realize up to three potential advantages, namely: the n-contacts 114, 116 do not block the path of the light emitted from the LEDs; the n-contacts 114, 116 and n-contact holes can be formed jointly with those of up to three adjacent pixels in a pixel array 210; and the location of the n-contacts 114, 116 enhances current spreading to provide a relatively uniform distribution of current across the pixel. However, in different examples, the shape, location, and number of n-contact holes can differ from those shown in the examples of FIG. 1 through FIG. 3.

According to some examples, the method includes forming n-type electrical contact(s) within the n-contact hole(s) in contact with the n-GaN layer 106 at operation 606. The n-contacts 114, 116 are formed in direct physical contact with the n-GaN layer 106 though the dry-etched n-contact holes penetrating the DBR 104 structure. The n-type contacts 114, 116 are formed from a conductive material suitable for providing current to a semiconductor device, such as a microLED pixel. In some examples, after depositing the n-contacts 114, 116 on the n-GaN layer 106, operation 606 includes a further annealing process to realize the ohmic contact between the n-GaN layer 106 and the n-contacts 114, 116. The annealing process may be necessary in some examples due to the resistance of the nanoporous silicon doped layers of the DBR 104 being greatly increased as a result of the electrochemical etching operation 518.

According to some examples, the method includes forming a gap 202, including a light-blocking material, between at least one pair of adjacent pixels of the pixel array 210 at operation 608. The gap 202 is formed between different pixels to block side light leakage, thereby addressing the technical problem of optical cross-talk in pixel arrays.

FIG. 7 illustrates a graph of reflectivity 706 across light wavelength 704 values of an example DBR. The DBR exhibits high reflectivity within a stopband 702, e.g., a photonic stopband. Because the DBR is a structure formed from multiple layers of alternating materials having a varying refractive index (e.g., the pairs of alternating adjacent silicon doped and undoped layers), the DBR exhibits periodic variation in the effective refractive index. Each layer boundary causes a partial reflection of an optical wave. In some examples, the thicknesses and refractive indices of the DBR layers are such that waves whose vacuum wavelength is close to four times the optical thickness of the layers are reflected by the DBR to combine with constructive interference. The range of wavelengths that are reflected is called the photonic stopband, e.g., stopband 702. Within this range of wavelengths, light is reflected by the DBR.

Thus, in some examples, the DBR 104 is configured to reflect a portion of the spectrum of the light from the one or more LEDs. In some examples, the thickness of the DBR layers is configured to provide a DBR stopband 702 centered on a center wavelength. In such examples, each DBR layer has a thickness L=λ(4n) wherein λ is the desired center wavelength for the stopband 702 and n is the refractive index of that layer. In some examples, the DBR 104 includes multiple color-specific DBRs, such as a blue DBR 416 with a center frequency chosen to reflect blue light, a green DBR 418 with a center frequency chosen to reflect green light, and a red DBR 420 with a center frequency chosen to reflect red light. Specific examples of color-specific DBRs and their respective center wavelengths are described below with reference to FIG. 8 and FIG. 10.

FIG. 8 shows a graph of wavelengths 806 of light against reflectance 802 of an example green DBR and an example red DBR of an example filtering DBR, and against electroluminescent intensity 804 for blue, green, and red microLEDs. Light emitted by a blue LED 414 is shown as blue light band 812, light emitted by a green LED 412 is shown as green light band 814, and light emitted by a red LED 410 is shown as red light band 816. Each light band 812, 814, 816 is characterized by a peak wavelength (respectively, blue light peak wavelength 818, green light peak wavelength 820, and red light peak wavelength 822), a lower wavelength band extending across lower wavelengths than the peak wavelength, and a higher wavelength band extending across higher wavelengths than the peak wavelength.

The red DBR 420 of the example filtering DBR is configured to provide a red DBR stopband 810 reflecting and thereby filtering light between the green light peak wavelength 820 and the red light peak wavelength 822. In particular, the red DBR stopband 810 in the illustrated example overlaps at least a portion of the lower wavelength band of the red light band 816. The red DBR 420 thereby effectively shifts the center wavelength of the red light band 816 toward higher wavelengths (e.g., it effects a red-shift of the light emitted by the red LED 410) and also narrows the bandwidth of the red light band 816. These two filter effects can be used in some examples to purify the perceived redness of the color of the red light 422 emitted by the pixel, causing it to appear more deeply red and less orange or yellow, as described in greater detail below with reference to FIG. 9.

The illustrated example also shows the red DBR stopband 810 overlapping a portion of the higher wavelength band of the green light band 814. In some examples, this overlap can be used to further enhance the perception of the green light 424 and red light 422 emitted by the pixel as being more distinct from each other and more purely green and red, respectively, as described in greater detail below with reference to FIG. 9.

The illustrated example also includes a green DBR 418 configured to provide a green DBR stopband 808 reflecting and thereby filtering light between the blue light band 812 and the green light band 814. In particular, the green DBR stopband 808 in the illustrated example overlaps at least a portion of the lower wavelength band of the green light band 814 and the higher wavelength band of the blue light band 812. The green DBR 418 thereby effectively shifts the center wavelength of the green light band 814 toward higher wavelengths (e.g., it effects a red-shift of the light emitted by the green LED 412), shifts the center wavelength of the blue light band 812 toward lower wavelengths (e.g., it effects a blue-shift of the light emitted by the blue LED 414), and narrows the bandwidths of both the green light band 814 and the blue light band 812. In some examples, this overlap can be used to further enhance the perception of the blue light 426 and green light 424 emitted by the pixel as being more distinct from each other and more purely blue and green, respectively, as described in greater detail below with reference to FIG. 9.

It will be appreciated that different examples may include one or more color-specific DBRs configured to each provide a stopband overlapping at least a portion of the lower wavelength band and/or the higher wavelength band of one or more light bands characterizing the light emitted by the one or more LEDs. By narrowing and/or shifting the center wavelength of one or more light bands, a given color-specific DBR of a filtering DBR can effectively enhance the purity or distinctness of one or more colors of light emitted by the pixel.

In some examples, the red DBR 420 includes pairs of alternating adjacent layers, as described above, wherein each silicon doped layer has a first refractive index and a first thickness, and wherein each un-doped layer has a second refractive index and a second thickness. The first refractive index (i.e., the refractive index of the nanoporous silicon doped layer after porosification by electrochemical etching) may be between 1.6 and 2, and the second refractive index (i.e., the refractive index of the un-doped layer) may be approximately 2.4 such that the ratio of the first refractive index to the second refractive index is between 0.6 and 0.9. Each layer's thickness is equal to the desired center wavelength of the DBR's photonic stopband (i.e. the red DBR stopband 810), divided by four, divided by the refractive index of the layer, as described above with reference to FIG. 7. Similar choices of materials and thicknesses of the alternating layers can be similarly selected for the green DBR 418, the blue DBR 416, and/or other color-specific DBRs based on the desired center frequencies for those color-specific DBRs in accordance with the same principles.

FIG. 9 shows a graph of peak emission wavelength 910 against bandwidth 912 (measured as full width at half maximum (FWHM)), indicating the apparent (i.e., as perceived by humans) color of light characterized by various points on the graph. Humans perceive as red any light falling within the red domain 902; humans perceive as green any light falling within the green domain 904; and humans perceive as blue any light falling within the blue domain 906. In particular, the three color domains 902, 904, 906 indicate the hues generally required for RGB display applications. The peak emission wavelength 910 of light generally corresponds to a peak wavelength or center wavelength of a spectrum band of the light.

The upward-curving shape of the red domain 902 and the downward-curving shape of the blue domain 906 have the consequence that, as the bandwidth 912 of red light or blue light emission increases, they are less likely to be perceived as red or blue respectively (e.g., they will not fall within the red domain 902 or blue domain 906 respectively) unless their peak emission wavelength 910 is shifted toward higher or lower wavelengths respectively. Thus, a red light is perceived as more purely red when its peak emission wavelength 910 is red-shifted and/or when its bandwidth 912 is decreased; similarly, a blue light is perceived as more purely blue when its peak emission wavelength 910 is blue-shifted and/or when its bandwidth 912 is decreased. The green domain 904 also exhibits a narrowing of apparently green peak emission wavelengths 910 as bandwidth 912 increases; thus, in some cases a green light is also more likely to be perceived as purely green when the green light band 814 has a lower bandwidth 912.

The diagonal line 908 indicates a trend line for the peak emission wavelength 910 and bandwidth 912 of light emitted by typical indium gallium nitride (InGaN) or gallium nitride (GaN) based LEDs. In particular, triangle 914 indicates where the light emission of an example InGaN converted phosphor falls on the graph, corresponding to emission of light perceived as reddish but somewhat orange. To achieve more purely red light emissions, significant amounts of indium are required for the fabrication of the quantum wells of the red LED, which is difficult to achieve and can lead to degraded LED performance in other respects. Thus, in some examples, a filtering DBR as described herein may address the technical problem of transforming the characteristics of light bands to increase the perceived purity of the color of their light, and specifically, of filtering the red light band 816 of light emitted by a red LED 410 to improve the perceived purity of the light emitted thereby without the use of large amounts of indium in manufacturing the red LED 410. Compared to other techniques for wavelength engineering, some examples described herein provide simple and efficient structures and fabrication techniques for achieving more apparently pure colored light.

Further details of the apparent color of LED light as a function of peak emission wavelength 910 and bandwidth 912 are described by [Y. Robin, M. Pristovsek, H. Amano, F. Oehler, R. A. Oliver, and C. J. Humphreys, “What is red? On the chromaticity of orange-red InGaN/GaN based LEDs”, Journal of Applied Physics 124, 183102 (2018)], which is hereby incorporated by reference in its entirety.

FIG. 10 shows a graph of wavelengths 806 of light against reflectance 802 of an example blue DBR, an example green DBR, and an example red DBR of an example RCLED DBR, and against electroluminescent intensity 804 for blue, green, and red microLEDs. Similarly to FIG. 8, FIG. 10 shows the electroluminescent intensity 804 of a blue light band 812, a green light band 814, and a red light band 816 emitted by the three colored LEDs, respectively. FIG. 10 also shows the reflectance 802 of the three color-specific DBRs as a blue DBR stopband 1002, a green DBR stopband 1004, and a red DBR stopband 1006.

In some examples using an RCLED design, the DBR 104 includes one or more color-specific DBRs configured to cooperate with a resonant cavity for each of one or more of the colored LEDs to collimate and intensify the light emitted by the pixel, e.g., blue light 426, green light 424, and/or red light 422. In some such examples, the length of a resonant cavity of the RCLED design is indicated as L_{cav}=λ/2, wherein L_{cav} is the thickness between the conductive mirror 406 and the DBR for the respective resonant cavity (e.g., the color-specific DBR 416, 418, or 420), and λ is the center wavelength 818, 820, or 822 of the respective LED's light emission band 812, 814, or 816. Thus, for example, resonance can be generated for the blue light emitted by the blue LED 414 by depositing the various layers of the pixel 102 such that the length between the conductive mirror 406 at the top of the third LED aperture 122 (housing the blue LED 414 in an example) and the blue DBR 416 is equal to half of the blue light peak wavelength 818, and by providing a blue DBR 416 having a blue DBR stopband 1002 centered on the blue light peak wavelength 818 as shown in FIG. 10.

### CONCLUSION

The examples described herein may address one or more technical problems, including but not limited to those identified herein. First, light emission by LEDs, and in particular monolithic RGB microLEDs, can be enhanced by the porosification of DBR layers using EC etching, assisted by the exposure of the DBR layers via the dry-etched apertures. Second, the technical problem of the low electrical conductivity of a nanoporous DBR can be addressed by providing an n-type electrical contact (n-contact) in direct physical contact with the n-GaN layer. Third, the technical problem of optical cross-talk between pixels in a horizontal pixel array can be addressed by forming a gap between pixels containing a light-blocking material. Fourth, light emission can be further enhanced by forming an optical resonant cavity designed to enhance and collimate the light output of the LED(s). In some examples, the fabrication techniques described herein provide precise lengths for resonant cavities by providing high uniformity of RCLED fabrication across entire wafers up to 12 inches in size. Furthermore, some RCLED examples described herein avoid the need for a complicated packaging process, including a specially design lens, to collimate the light emitted by the LEDs. Sixth, the DBR can act as a filter to purify the color of one or more of the LEDs by shifting and narrowing the wavelength band of the LEDs' emitted light. Seventh, the precise control of thickness and integration uniformity enabled by the epitaxy techniques described herein may provide a DBR having improved uniformity and quality across a whole semiconductor wafer relative to conventional dry etching, grinding, and chemical vapor deposition (CVD) approaches applied across a large wafer area. The described techniques may also provide highly uniform n-GaN layers across the whole semiconductor wafer. Eighth, examples described herein address the technical problem of how to efficiently fabricate an effective DBR for polychromatic (e.g., RGB) LEDs, including microLEDs.

### Glossary

Terms such as “above”, “below”, “upper”, “lower”, and other relative vertical positions are intended in this disclosure to refer to the relative positions of various features with respect to a frame of reference in which a surface normal to a substrate surface used in semiconductor fabrication, such as a crystalline substrate surface, defines an upward direction. It will be appreciated that the portions of a fabricated semiconductor device farther from the substrate surface are referred to as “above” those portions closer to the substrate surface, even though the semiconductor device may be fabricated in contact with the substrate surface at any orientation relative to the Earth's gravitational field or any other frame of reference, and even though the semiconductor device may be used in any orientation after fabrication.

What is claimed is:

1. A device, comprising:
a light emitting diode (LED) configured to emit light characterized by a peak wavelength, a lower wavelength band extending across lower wavelengths than the peak wavelength, and a higher wavelength band extending across higher wavelengths than the peak wavelength;
a reflector positioned in a first direction from the LED; and
a distributed Bragg reflector (DBR):
having a lower reflectance than the reflector;
positioned in a second direction from the LED opposite the first direction; and
configured to block light within a stopband overlapping a portion of the lower wavelength band or a portion of the higher wavelength band but not overlapping the peak wavelength, such that the DBR propagates filtered light in the second direction.

2. The device of claim 1, wherein:
the LED is a red LED configured to emit light with a peak wavelength between 550 nanometers (nm) and 750 nm; and
the stopband overlaps a portion of the lower wavelength band of the LED.

3. The device of claim 2, wherein:
the peak wavelength of the light of the red LED is between 600 nm and 620 nm; and
the stopband is centered on a wavelength between 550 nm and 580 nm.

4. The device of claim 1, wherein:
the DBR comprises a plurality of pairs of alternating adjacent layers, each pair of alternating adjacent layers comprising:
a silicon doped layer comprising gallium nitride (GaN) and silicon (Si); and
an un-doped layer comprising gallium nitride (GaN) and having a lower silicon content than the silicon doped layer.

5. The device of claim 4, wherein:
at least one pair of alternating adjacent layers of the DBR is characterized by:
the silicon doped layer having a first refractive index and a first thickness; and
the un-doped layer having a second refractive index and a second thickness; and
a ratio of the first thickness to the second thickness is configured based on a desired center wavelength of the stopband of the DBR.

6. The device of claim 5, wherein:
the LED is a red LED configured to emit light with a peak wavelength between 550 nanometers (nm) and 750 nm;
the first refractive index is between 1.6 and 2;
a ratio of the first refractive index to the second refractive index is between 0.6 and 0.9;
the first thickness is equal to the desired center wavelength of the stopband, divided by four, divided by the first refractive index; and
the second thickness is equal to the desired center wavelength of the stopband, divided by four, divided by the second refractive index.

7. The device of claim 1,
further comprising a second LED configured to emit light characterized by a second LED peak wavelength lower than the peak wavelength of the LED, a second LED lower wavelength band, and a second LED upper wavelength band;
wherein the stopband of the DBR overlaps a portion of the lower wavelength band and a portion of the second LED upper wavelength band.

8. The device of claim 7, wherein:
the LED is a red LED configured to emit light with a peak wavelength between 550 nanometers (nm) and 750 nm; and
the second LED is a green LED.

9. The device of claim 8, wherein:
the peak wavelength of the light of the red LED is between 600 nm and 620 nm; and
the stopband is centered on a wavelength between 550 nm and 580 nm.

10. The device of claim 8, further comprising:
a second DBR configured to block light within a stopband overlapping a portion of the second LED lower wavelength band.

11. The device of claim 8, further comprising:
a second reflector positioned in the first direction from the second LED; and
a second DBR configured to block light within a stopband overlapping the peak wavelength of the light of the second LED, such that the second DBR and the reflector define a resonant cavity having a length effective to collimate at least one wavelength of the light of the second LED.

12. A method of fabricating a semiconductor device, comprising:
forming, above a substrate surface, a plurality of layers to form a distributed Bragg reflector (DBR) configured to block light within a stopband;
growing, above the DBR, a light emitting diode (LED) configured to emit light characterized by a peak wavelength, a lower wavelength band extending across lower wavelengths than the peak wavelength, and a higher wavelength band extending across higher wavelengths than the peak wavelength, wherein the stopband of the DBR overlaps a portion of the lower wavelength band or a portion of the higher wavelength band but not the peak wavelength; and
forming, above the LED, a reflector having a higher reflectance than the DBR.

13. The method of claim 12, further comprising:
forming, above the DBR, an n-GaN layer comprising gallium nitride;
forming, above the n-GaN layer, a dielectric layer; and
dry etching a micro-hole in the dielectric layer,
wherein the LED is grown within the micro-hole.

14. The method of claim 12, wherein:
the LED is a red LED configured to emit light with a peak wavelength between 550 nanometers (nm) and 750 nm; and
the stopband overlaps a portion of the lower wavelength band of the LED.

15. The method of claim 14, wherein:
the peak wavelength of the light of the red LED is between 600 nm and 620 nm; and
the stopband is centered on a wavelength between 550 nm and 580 nm.

16. The method of claim 12, wherein:
the DBR comprises a plurality of pairs of alternating adjacent layers, each pair of alternating adjacent layers comprising:
a silicon doped layer comprising gallium nitride (GaN) and silicon (Si); and
an un-doped layer comprising gallium nitride (GaN) and having a lower silicon content than the silicon doped layer.

17. The method of claim 16, wherein:
at least one pair of alternating adjacent layers of the DBR is characterized by:
the silicon doped layer having a first refractive index and a first thickness; and
the un-doped layer having a second refractive index and a second thickness; and
a ratio of the first thickness to the second thickness is configured based on a desired center wavelength of the stopband of the DBR.

18. The method of claim 17, wherein:
the LED is a red LED configured to emit light with a peak wavelength between 550 nanometers (nm) and 750 nm;
the first refractive index is between 1.6 and 2;
a ratio of the first refractive index to the second refractive index is between 0.6 and 0.9;
the first thickness is equal to the desired center wavelength of the stopband, divided by four, divided by the first refractive index; and
the second thickness is equal to the desired center wavelength of the stopband, divided by four, divided by the second refractive index.

19. The method of claim 13, further comprising:
dry etching a second micro-hole in the dielectric layer; and
growing, in the second micro-hole, a second LED configured to emit light characterized by a second LED peak wavelength lower than the peak wavelength of the LED, a second LED lower wavelength band, and a second LED upper wavelength band;
wherein the stopband of the DBR overlaps a portion of the lower wavelength band and a portion of the second LED upper wavelength band.

20. The method of claim 19, wherein:
the LED is a red LED configured to emit light with a peak wavelength between 550 nanometers (nm) and 750 nm; and
the second LED is a green LED.

21. The method of claim 19, further comprising:
forming a second DBR configured to block light within a stopband overlapping a portion of the second LED lower wavelength band.

22. The method of claim 19, further comprising:
forming, above the second LED, a second reflector, and
forming a second DBR configured to block light within a stopband overlapping the peak wavelength of the light of the second LED, such that the second DBR and the reflector define a resonant cavity having a length effective to collimate at least one wavelength of the light of the second LED.
